(19) United States
(12) Patent Application Publication
(10) Pub. No.: US 2024/0408749 A1
(43) Pub. Date: Dec. 12, 2024

(54) ROBOT SIMULATION APPARATUS

(71) Applicant: FANUC CORPORATION, Minamitsuru-gu, Yamanashi (JP)

(72) Inventor: Hiroyuki YONEYAMA, Yamanashi (JP)

(21) Appl. No.: 18/274,098

(22) PCT Filed: Feb. 14, 2022
(86) PCT No.: PCT/JP2022/005753

§ 371 Date: Jul. 25, 2023

(30) Foreign Application Priority Data
Feb. 18, 2021 (JP) 2021-024351

(51) Int. Cl. B25J 9/16; G06F 30/17

(52) U.S. Cl. CPC B25J 9/1605; G06F 30/17

(57) ABSTRACT

A robot simulation device simulates an operation program for a robot of a robot system. The robot simulation device includes a robot model arrangement unit that arranges a robot model in a virtual space, a grasped object model arrangement unit that arranges a grasped object model, a work object model arrangement unit that arranges a work object model of a work object, an image generation unit that generates an image of the robot system operating according to the operation program, a display unit that displays the generated image, a first transfer material image display unit that displays a transfer material image of a transfer material on the surface of the grasped object model, and a second transfer material image display unit that, when the surfaces of the grasped object model and the work object model contact, displays the transfer material image on the surface of the inverted work object model.

### TECHNICAL FIELD

The present invention relates to a robot simulation apparatus.

### BACKGROUND ART

A technique is proposed in which a three-dimensional model of a robot system, which includes a robot mounted with a tool, a workpiece, and peripheral equipment, is arranged and displayed on a screen at the same time, and operation of an operation program for a robot is simulated on a computer. See, for example, Patent Document 1.
Patent Document 1: Japanese Unexamined Patent Application, Publication No. 2016-129915

### DISCLOSURE OF THE INVENTION

### Problems to be Solved by the Invention

For example, in the case of confirming an operation program for a robot to press a roller grasped by the robot against a workpiece, which is a plane block to attach a pattern on the roller (for example, a seal) to the plane block or in the case of confirming an operation program for a robot to attach a label such as a seal or a stamp to a workpiece flowing on a belt conveyor, it is not possible to confirm the state of attaching the pattern on the roller to the plane block or the state of attaching the label to the workpiece by simulation in advance, and a worker has to directly confirm the state at the site.

Therefore, it is desired to be able to easily confirm, together with the operation of an operation program, that a pattern, a label or the like has reliably been transferred to a workpiece.

### Means for Solving the Problems

One aspect of a robot simulation apparatus of the present disclosure is a robot simulation apparatus for performing simulation of an operation program for a robot that, in a robot system including the robot grasping a grasped object and a workpiece in a workspace, presses a surface of the grasped object to a surface of the workpiece to transfer a transfer material arranged on the surface of the grasped object onto the surface of the workpiece, the robot simulation apparatus including: a robot model arrangement unit configured to arrange a robot model of the robot in a virtual space that three-dimensionally represents the workspace; a grasped object model arrangement unit configured to arrange a grasped object model of the grasped object such that the grasped object model is grasped by the robot model, in the virtual space; a workpiece model arrangement unit configured to arrange a workpiece model of the workpiece at a position that the grasped object model grasped by the robot model reaches, in the virtual space; an image generation unit configured to generate, in the robot simulation apparatus, an image of the robot system operating according to the operation program; a display unit configured to display the image of the robot system generated by the image generation unit; a first transfer material image display unit configured to display a transfer material image of the transfer material on a surface of the grasped object model; and a second transfer material image display unit configured to display, when the surface of the grasped object model comes into contact with a surface of the workpiece model, the transfer material image on the surface of the workpiece model such that the transfer material image is in a relationship of being reversed relative to the transfer material image displayed on the surface of the grasped object model.

### Effects of the Invention

According to one aspect, it is possible to easily confirm, together with operation of an operation program, that a pattern, a label or the like has reliably been transferred to a workpiece.

### BRIEF DESCRIPTION OF THE DRAWINGS

FIG. 1 is a functional block diagram showing a functional configuration example of a robot simulation apparatus according to a first embodiment;

FIG. 2 is a diagram showing an example of an image of a robot system generated by an image generation unit;

FIG. 3A is a diagram showing an example of a generated image;

FIG. 3B is a diagram showing an example of a generated image;

FIG. 4 is a diagram showing an example of a transfer material image of a transfer material;

FIG. 5 is a diagram showing an example of the transfer material image of FIG. 4 displayed on the surface of a grasped object model;

FIG. 6A is a diagram showing an example of the transfer material image transferred onto the surface of a workpiece model according to a motion of a robot model;

FIG. 6B is a diagram showing an example of the transfer material image transferred onto the surface of the workpiece model according to a motion of the robot model;

FIG. 6C is a diagram showing an example of the transfer material image transferred onto the surface of the workpiece model according to a motion of a robot model;

FIG. 7 is a diagram showing an example of a transfer material image of the whole transfer material reversedly transferred;

FIG. 8 is a flowchart illustrating a simulation process of the robot simulation apparatus;

FIG. 9 is a functional block diagram showing a functional configuration example of a robot simulation apparatus according to a second embodiment;

FIG. 10 is a diagram showing an example of a screen of a virtual space displayed on a display unit;

FIG. 11 is a diagram showing an example of an image of a robot system generated by an image generation unit;

FIG. 12 is a diagram showing an example of a transfer material image of a transfer material displayed being superimposed on the image of the robot system of FIG. 10;

FIG. 13 is a diagram showing an example of a transfer material image transferred onto the surface of a workpiece model; and

FIG. 14 is a diagram showing an example of the whole transfer material image reversedly transferred, which is superimposedly displayed on the image of FIG. 13.

### PREFERRED MODE FOR CARRYING OUT THE INVENTION

### First Embodiment

A configuration of the present embodiment will be described in detail using drawings. Here, a case is exemplified in which, in a workspace, a robot grasps a roller, and presses the grasped roller to a plane block, which is a workpiece in a flat plate shape, to attach a seal or the like on the roller to the plane block. The present invention is also applicable to the case of attaching a seal or the like on a roller grasped by a robot, to a workpiece in any shape.

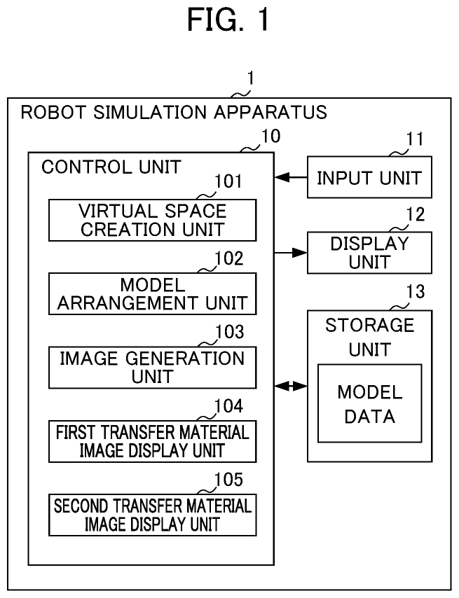

FIG. 1 is a functional block diagram showing a functional configuration example of a robot simulation apparatus according to the first embodiment.

As shown in FIG. 1, a robot simulation apparatus 1 is a well-known computer and includes a control unit 10, an input unit 11, a display unit 12, and a storage unit 13. The control unit 10 includes a virtual space creation unit 101, a model arrangement unit 102, an image generation unit 103, a first transfer material image display unit 104, and a second transfer material image display unit 105. The storage unit 13 includes model data 131.

The robot simulation apparatus 1 may be mutually connected to a robot control apparatus (not shown) that controls motions of the robot (not shown) via a network such as a LAN (local area network) or the Internet. Or alternatively, the robot simulation apparatus 1 may be mutually directly connected to the robot control apparatus (not shown) via connection interfaces not shown.

### <Input Unit 11>

The input unit 11 is, for example, a keyboard, a touch panel arranged on the display unit 12 described later, or the like, and accepts input from a worker.

### <Display Unit 12>

The display unit 12 is, for example, a liquid crystal display. The display unit 12 displays, for example, 3D CAD data or the like of the robot (not shown), a grasped object such as the roller grasped by the robot, and a workpiece such as the plane block to which the grasped object is pressed, which have been inputted by the worker via the input unit 11, as described later.

### <Storage Unit 13>

The storage unit 13 is an SSD (solid state drive), an HDD (hard disk drive), or the like, and may store, together with various kinds of control programs, an operation program for the robot that presses the surface of the grasped object, such as a roller, to the surface of the workpiece, which is a plane block, and transfers a transfer material arranged on the surface of the grasped object to the surface of the workpiece, the model data 131, and the like.

The model data 131 stores, for example, the 3D CAD data of the robot (not shown) (hereinafter also referred to as a “robot model”), the 3D CAD data of the grasped object, such as a roller, grasped by the robot (hereinafter also referred to as a “grasped object model”), and the 3D CAD data of the workpiece, such as a plane block, to which the grasped object is to be pressed, and the like, which have been inputted (selected) by the worker via the input unit 11 and displayed on the display unit 12 as described above.

### <Control Unit 10>

The control unit 10 has a CPU (central processing unit), a ROM (read-only memory), a RAM (random access memory), a CMOS (complementary metal-oxide-semiconductor) memory, and the like, which are configured to be mutually communicable via a bus and are well known to one skilled in the art.

The CPU is a processor that performs overall control of the robot simulation apparatus 1. The CPU reads a system program and an application program stored in the ROM via the bus, and controls the whole robot simulation apparatus 1 according to the system program and the application program. Thereby, as shown in FIG. 1, the control unit 10 is configured to realize functions of the virtual space creation unit 101, the model arrangement unit 102, the image generation unit 103, the first transfer material image display unit 104, and the second transfer material image display unit 105. In the RAM, various kinds of data such as temporary calculation data and display data are stored. The CMOS memory is backed up by a battery not shown and is configured as a nonvolatile memory in which a storage state is maintained even if the power source of the robot simulation apparatus 1 is turned off.

The virtual space creation unit 101 creates a virtual space that three-dimensionally represents a workspace in which the robot (not shown), the grasped object such as a roller, and the workpiece which is a plane block are arranged.

For example, the model arrangement unit 102 has a function as a robot model arrangement unit that arranges the robot model of the robot (not shown) in the three-dimensional virtual space created by the virtual space creation unit 101 in response to an input operation by a user via the input unit 11, a function as a grasped object model arrangement unit that arranges the grasped model of the roller (the grasped object), and a function as a workpiece model arrangement unit that arranges the workpiece model of the plane block (the workpiece).

Specifically, the model arrangement unit 102 (the robot model arrangement unit) reads the robot model of the robot from the model data 131 in the storage unit 13 so as to arrange the robot not shown in the virtual space. The model arrangement unit 102 (the robot model arrangement unit) arranges the read robot model of the robot in the virtual space.

Further, the model arrangement unit 102 (the grasped object model arrangement unit) reads the grasped object model of the roller from the model data 131 in the storage unit 13 so as to arrange the grasped object model of the roller not shown in the virtual space. The model arrangement unit 102 (the grasped object model arrangement unit) arranges the read grasped object model of the roller in the virtual space.

Further, the model arrangement unit 102 (the workpiece model arrangement unit) reads the workpiece model of the plane block from the model data 131 in the storage unit 13 so as to arrange the workpiece model of the plane block not shown in the virtual space. The model arrangement unit 102 (the workpiece model arrangement unit) arranges the read workpiece model of the plane block in the virtual space.

The image generation unit 103 generates an image of the robot system operating on the robot simulation apparatus 1 according to the operation program.

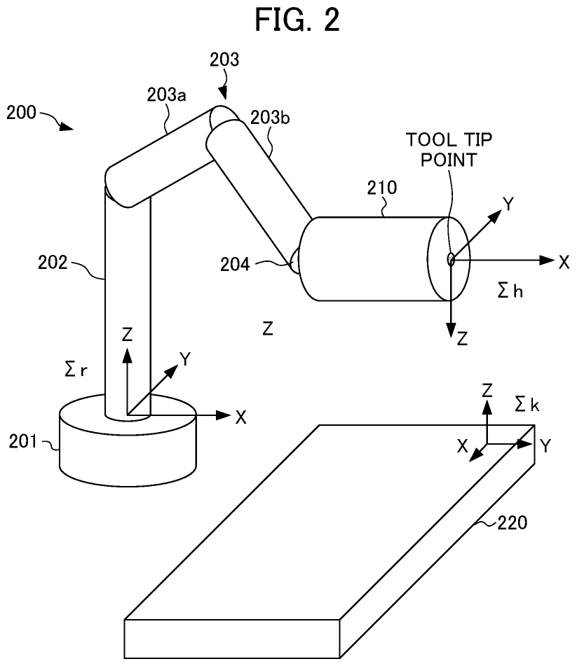

FIG. 2 is a diagram showing an example of an image of the robot system generated by the image generation unit 103.

As shown in FIG. 2, on the generated image, a robot model 200, a grasped object model 210, and a workpiece model 220 are arranged.

The robot model 200 is a three-dimensional model of a vertical articulated robot that moves, grasping a grasped object such as a roller, and has a robot base model 201, a turning body model 202, a robot arm model 203, and a wrist portion model 204.

The robot arm model 203 has an upper arm portion model 203a that is rotatably connected with the turning body model 202, and a forearm portion model 203b that is rotatably connected with the tip of the upper arm portion model 203a.

The wrist portion model 204 is provided on the tip of the forearm portion model 203b and supports the grasped object model 210 such that the grasped object model 210 is rotatable around the three axes.

The operation program for the robot has virtual robot operation parameters for causing the robot model 200 to make operations. The virtual robot operation parameters include parameters of the origin and axis directions of a robot coordinate system Σr, the origin and axis directions of a grasped object coordinate system Σh, a maximum drive speed, a virtual movable range, and the like.

The robot coordinate system Σr is a coordinate system to be a basis at the time of causing the robot model 200 to make operations in the virtual space, and is defined in the virtual space by the origin and axis directions of the robot coordinate system Σr included among the virtual robot operation parameters.

As shown in FIG. 2, the origin of the robot coordinate system Σr is arranged at the center of the robot base model 201, and the turning body model 202 rotates around the Z axis of the robot coordinate system Σr.

The grasped object coordinate system Σh is a coordinate system that specifies the position and posture of the grasped object model 210 in the virtual space, and is defined in the virtual space by the origin and axis directions of the grasped object coordinate system Σh included among the virtual robot operation parameters.

As shown in FIG. 2, the origin of the grasped object coordinate system Σh is arranged to correspond to a tool tip point which is the rotation axis of the grasped object model 210 of the roller, and the grasped object model 210 rotates around the X axis of the grasped object coordinate system Σh.

The workpiece coordinate system Σk is a coordinate system to be a basis at the time of arranging the workpiece model 220 in the virtual space, and is defined in the virtual space by the origin and axis directions of the workpiece coordinate system Σk included among the virtual robot operation parameters.

As shown in FIG. 2, the origin of the workpiece coordinate system Σk is arranged on the upper surface of the workpiece model 220, and the axis directions of the workpiece coordinate system Σk are set such that the direction in which a transfer material image of a transfer material to be described later is transferred by the grasped object model 210 is the X axis, and the vertical direction relative to the upper surface of the workpiece model 220 is the Z axis.

Thereby, by executing the operation program for the robot, the robot simulation apparatus 1 can control the position of the tool tip point of the grasped object model 210, for example, to press the roller to the plane block to attach a seal or the like on the roller. Then, the image generation unit 103 generates an image of the robot system operating on the robot simulation apparatus 1 according to the operation program.

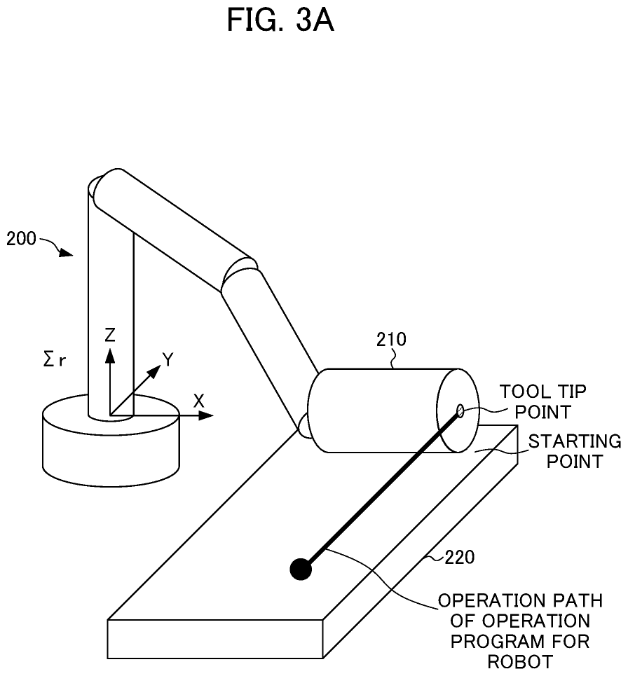

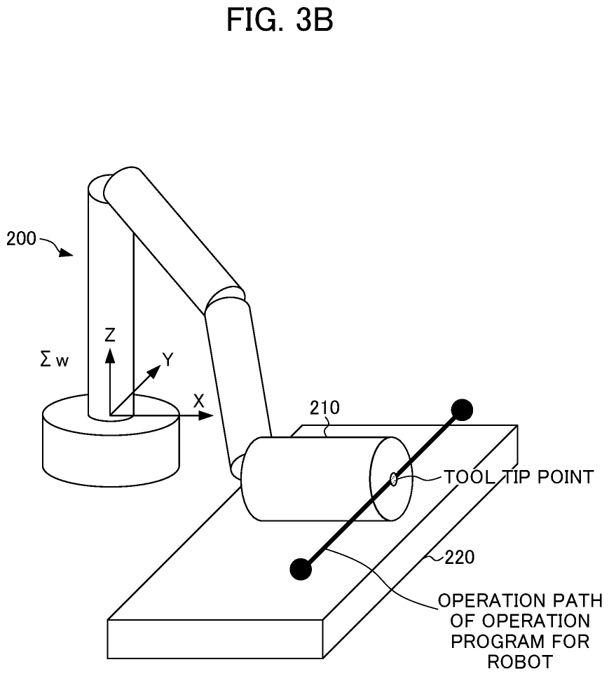

FIGS. 3A and 3B are diagrams showing examples of the generated image.

The image generation unit 103 displays the generated image on the display unit 12.

The first transfer material image display unit 104 displays a transfer material image of a transfer material to be transferred to the workpiece model 220, on the surface of the grasped object model 210.

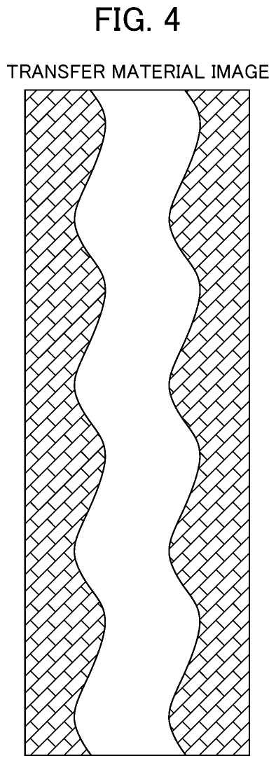

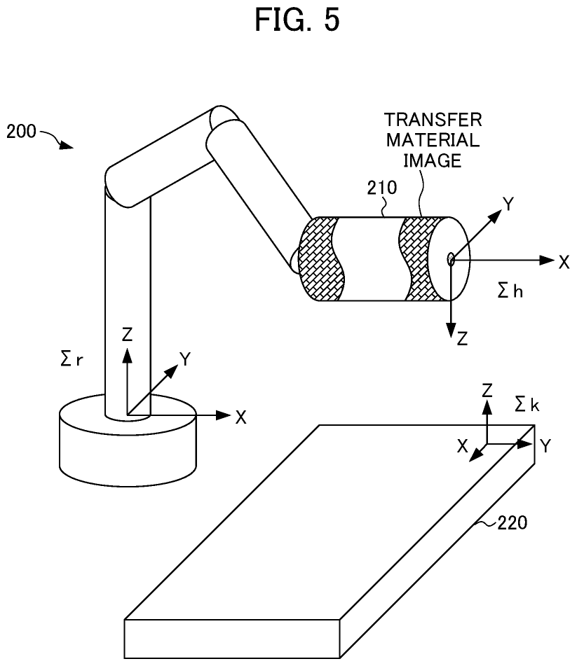

FIG. 4 is a diagram showing an example of the transfer material image of the transfer material. FIG. 5 is a diagram showing an example of the transfer material image of FIG. 4 displayed on the surface of the grasped object model 210.

As shown in FIG. 5, the first transfer material image display unit 104 displays the transfer material image of the transfer material on the image of FIG. 2, in a state of being wrapped around the surface of the grasped object model 210.

The first transfer material image display unit 104 may superimposingly display the transfer material image of the whole transfer material of FIG. 4 on the image of FIG. 2 as well as displaying the transfer material image of the transfer material on the surface of the grasped object model 210.

When the surface of the grasped object model 210 comes into contact with the surface of the workpiece model 220, the second transfer material image display unit 105 displays the transfer material image on the surface of the workpiece model 220 on the display unit 12 such that the transfer material image is in a relationship of being reversed relative to the transfer material image displayed on the surface of the grasped object model 210.

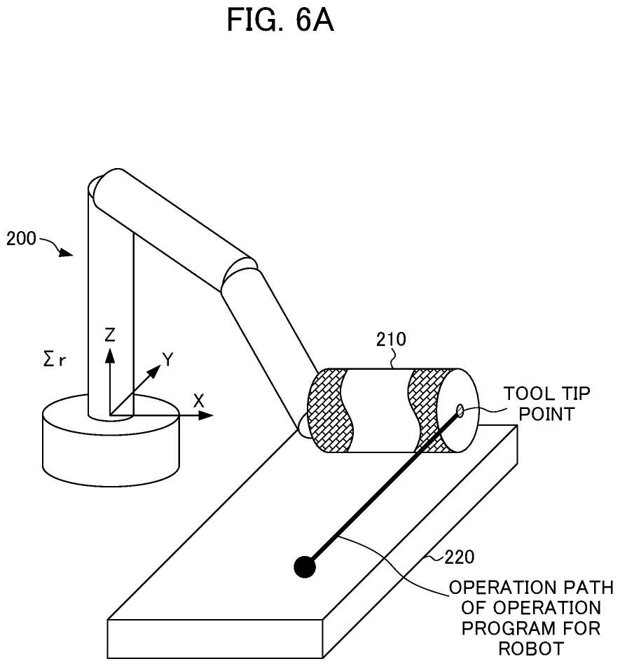

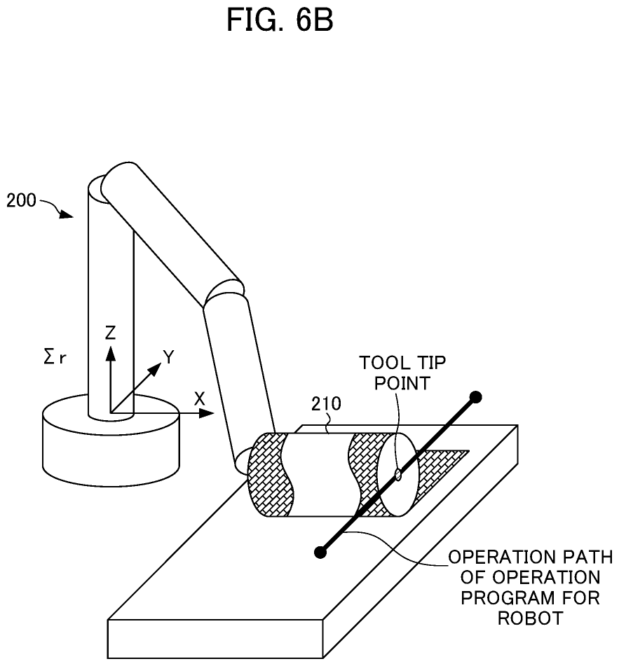

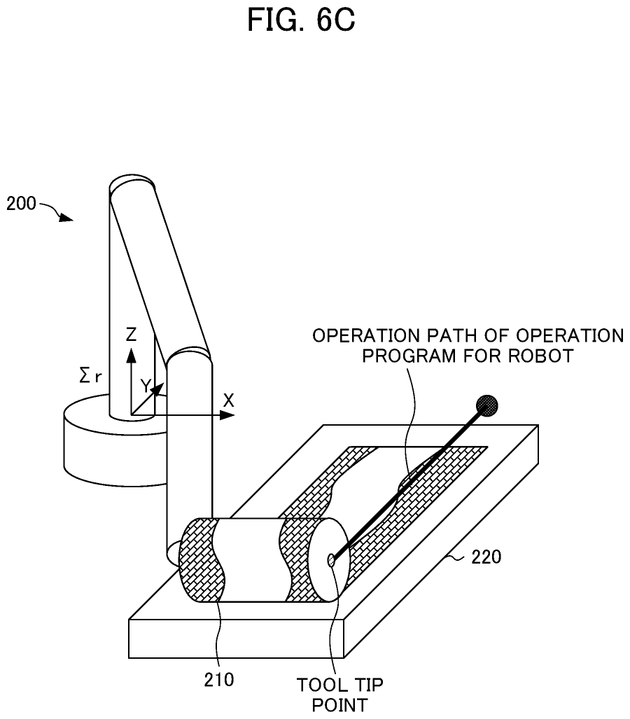

FIGS. 6A to 6C are diagrams showing examples of the transfer material image transferred onto the surface of the workpiece model 220 according to a motion of the robot model 200.

The second transfer material image display unit 105 may superimposingly display the whole transfer material image reversedly transferred to the workpiece model 220, on the display unit 12, as well as displaying each of the images of FIGS. 6A to 6C on the display unit 12.

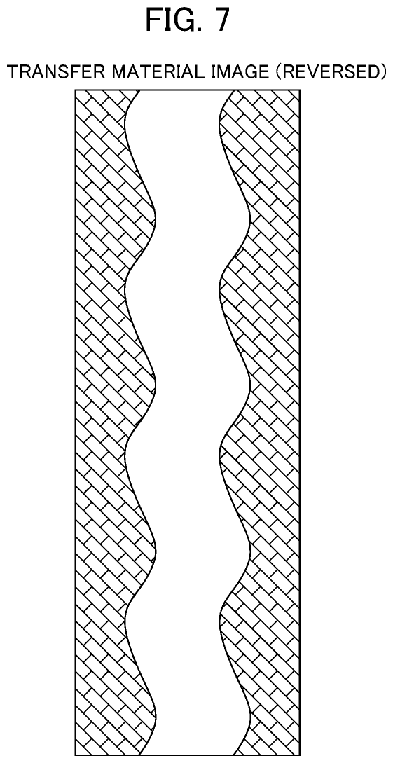

FIG. 7 is a diagram showing an example of the transfer material image of the reversedly transferred whole transfer material.

Then, if the transfer material is attached to the upper surface of the workpiece model 220 as shown in FIGS. 6A to 6C, the robot simulation apparatus 1 (the second transfer material image display unit 105) may judge that the operation program for the robot has been appropriately constructed.

On the other hand, in the case of failing in attaching the transfer material to the upper surface of the workpiece model 220, the robot simulation apparatus 1 (the second transfer material image display unit 105) may judge that the operation program for the robot has not been appropriately constructed. In this case, the robot simulation apparatus 1 may display a warning image on the display unit 12.

By doing so, the robot simulation apparatus 1 can simulate motions of the robot in the real space, in a form close to actual work, and easily confirm a pattern, a label or the like has reliably been transferred to a workpiece.

### <Simulation Process of Robot Simulation Apparatus 1>

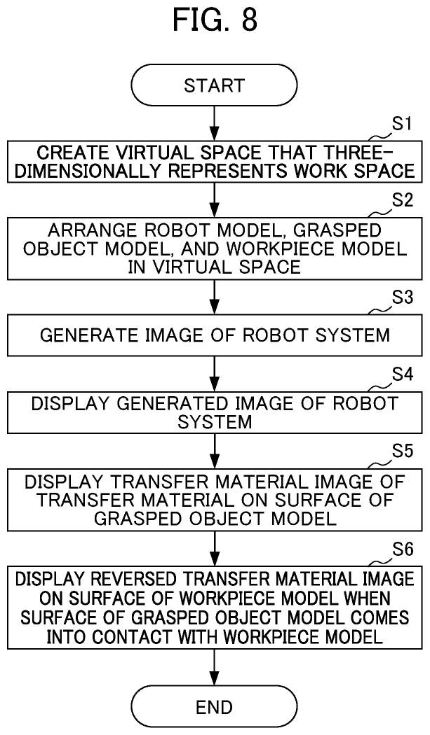

Next, the flow of a simulation process of the robot simulation apparatus 1 will be described with reference to FIG. 8.

FIG. 8 is a flowchart illustrating the simulation process of the robot simulation apparatus 1. The flow shown here is executed each time the operation program for the robot is executed.

At Step S1, the virtual space creation unit 101 creates a virtual space that three-dimensionally represents the workspace in which the robot, the roller, and the plane block are arranged.

At Step S2, the model arrangement unit 102 arranges the robot model 200 of the robot, the grasped object model 210 of the roller, and the workpiece model 220 of the plane block in the three-dimensional virtual space created at Step S1.

At Step S3, the image generation unit 103 generates an image of the robot system operating on the robot simulation apparatus 1 according to the operation program.

At Step S4, the image generation unit 103 displays the image of the robot system generated at Step S3 on the display unit 12.

At Step S5, the first transfer material image display unit 104 displays a transfer material image of a transfer material on the surface of the grasped object model 210 in the image displayed at Step S4.

At Step S6, when the surface of the grasped object model 210 comes into contact with the surface of the workpiece model 220, the second transfer material image display unit 105 displays the transfer material image on the surface of the workpiece model 220 on the display unit 12 according to motions of the robot model 200 and the grasped object model 210 such that the transfer material image is in a relationship of being reversed relative to the transfer material image displayed on the surface of the grasped object model 210.

As described above, the robot simulation apparatus 1 according to the first embodiment arranges the robot model 200, the grasped object model 210, and the workpiece model 220 in a virtual space. The robot simulation apparatus 1 generates an image of the robot system operating on the robot simulation apparatus 1 according to the operation program, displays the image on the display unit 12, and displays a transfer material image of a transfer material on the surface of the grasped object model 210 in the displayed image. When the surface of the grasped object model 210 comes into contact with the surface of the workpiece model 220, the robot simulation apparatus 1 displays the transfer material image on the surface of the workpiece model 220 on the display unit 12 such that the transfer material image is in a relationship of being reversed relative to the transfer material image displayed on the surface of the grasped object model 210, according to a motion of the robot model 200.

Thereby, the robot simulation apparatus 1 can easily confirm, together with operation of the operation program, that a pattern, a label or the like has reliably been transferred to a workpiece.

The first embodiment has been described above.

Next, a second embodiment will be described. The second embodiment is different from the first embodiment in that the robot system further includes a conveyance apparatus conveying the workpiece and a detection apparatus detecting the workpiece being conveyed by the conveyance apparatus; the robot simulation apparatus further includes: a conveyance model arrangement unit arranging a conveyance apparatus model of the conveyance apparatus in the virtual space; a workpiece model arrangement unit arranging the workpiece model of the workpiece on the conveyance apparatus model; and a detection apparatus model arrangement unit arranging a detection apparatus model of the detection apparatus detecting the workpiece model conveyed by the conveyance apparatus model such that the detection apparatus model is able to detect the workpiece model conveyed by the conveyance apparatus model; and the second transfer material image display unit further displays, when the surface of the grasped object model comes into contact with the surface of the workpiece model conveyed by the conveyance apparatus model, the transfer material image on the surface of the workpiece model such that the transfer material image is in a relationship of being reversed relative to the transfer material image displayed on the surface of the grasped object model.

Thereby, a robot simulation apparatus 1A according to the second embodiment can easily confirm, together with operation of the operation program, that a pattern, a label or the like has reliably been transferred to a workpiece.

Next, a second embodiment will be described.

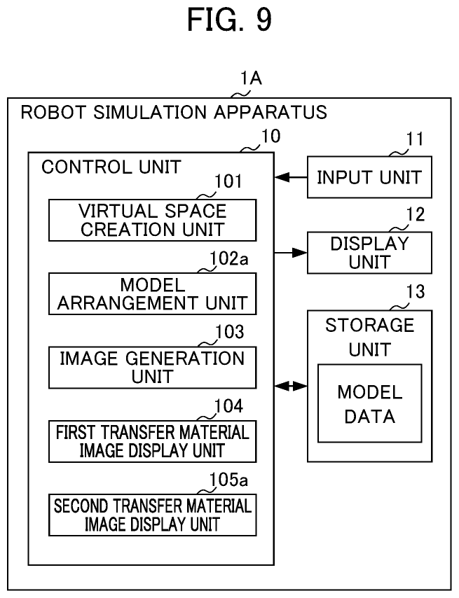

FIG. 9 is a functional block diagram showing a functional configuration example of a robot simulation apparatus according to the second embodiment. Components having similar functions to those of components of the robot simulation apparatus 1 of FIG. 1 will be given the same reference numerals, and detailed description thereof will be omitted.

The robot simulation apparatus 1A includes a control unit 10, an input unit 11, a display unit 12, and a storage unit 13. The control unit 10 includes a virtual space creation unit 101, a model arrangement unit 102a, an image generation unit 103, a first transfer material image display unit 104, and a second transfer material image display unit 105a. The storage unit 13 includes model data 131.

The control unit 10, the input unit 11, the display unit 12, and the storage unit 13 have functions equivalent to those of the control unit 10, the input unit 11, the display unit 12, and the storage unit 13 according to the first embodiment, respectively.

The storage unit 13 may store, together with an operation program for a robot, an operation program for causing the conveyance apparatus to operate. The model data 131 of the storage unit 13 may store, together with 3D CAD data of the robot (not shown) (a robot model), 3D CAD data of the grasped object grasped by the robot (a grasped object model), and 3D CAD data of the workpiece to which the grasped object is to be pressed (a workpiece model), which are displayed on the display unit 12, 3D CAD data of the conveyance apparatus such as a belt conveyor (hereinafter also referred to as a “conveyance apparatus model”) and 3D CAD data of the detection apparatus such as a three-dimensional visual sensor that detects the workpiece model conveyed by the conveyance apparatus model (hereinafter also referred to as a “detection apparatus model”).

The virtual space creation unit 101, the image generation unit 103, and the first transfer material image display unit 104 have functions equivalent to those of the virtual space creation unit 101, the image generation unit 103, and the first transfer material image display unit 104 according to the first embodiment, respectively.

For example, the model arrangement unit 102a has, together with a function as a robot model arrangement unit that arranges the robot model of the robot (not shown) in the three-dimensional virtual space created by the virtual space creation unit 101 in response to an input operation by a user via the input unit 11, and a function as a grasped object model arrangement unit that arranges the grasped model of the grasped object, a function as a conveyance apparatus model arrangement unit that arranges the conveyance apparatus model of the conveyance apparatus, a function as a workpiece model arrangement unit that arranges the workpiece model of a workpiece (the workpiece), and a function as a detection apparatus model arrangement unit that arranges the detection apparatus model of the detection apparatus such as a three-dimensional visual sensor such that the detection apparatus model is able to detect the workpiece model conveyed by the conveyance apparatus model.

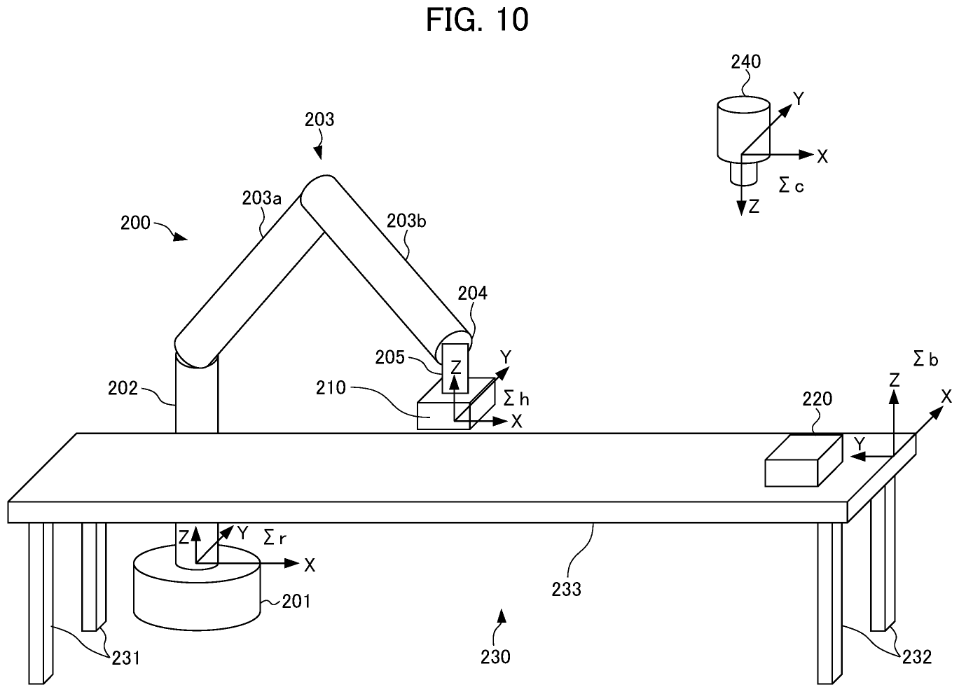

FIG. 10 is a diagram showing an example of a screen of the virtual space displayed on the display unit 12. Though the workpiece of the grasped object model 210 of FIG. 10 has a rectangular parallelepiped shape, it may have any shape such as a cylindrical shape.

Similarly to the case of the first embodiment, the robot model 200 is a three-dimensional model of a vertical articulated robot that moves, grasping a grasped object such as a stamp pad, and has a robot base model 201, a turning body model 202, a robot arm model 203, a wrist portion model 204, and a robot hand model 205.

The robot hand model 205 has, for example, a plurality of openable and closable finger portions or an adsorption portion, and holds the grasped object model 210 such as a stamp pad.

A conveyance apparatus model 230 is a three-dimensional model of the conveyance apparatus capable of conveying a workpiece (for example, a belt conveyor), which has support portion models 231 and 232, a conveyor model 233 movably provided on the support portion models 231 and 232. The conveyance apparatus model 230 conveys the workpiece model 220.

A detection apparatus model 240 is, for example, a three-dimensional visual sensor or the like, which is provided vertically above the conveyance apparatus model 230 and detects the workpiece model 220 conveyed by the conveyance apparatus model 230.

The operation program for the robot has virtual robot operation parameters for causing the robot model 200 to make operations. The virtual robot operation parameters include parameters of the origin and axis directions of a robot coordinate system Σr, the origin and axis directions of a grasped object coordinate system Σh, the origin and axis directions of a detection apparatus coordinate system Σc, a maximum drive speed, a virtual movable range, and the like.

The operation program for the conveyance apparatus has virtual conveyance apparatus operation parameters for causing the conveyance apparatus model 230 to operate. The virtual apparatus operation parameters include parameters of the origin and axis directions of a conveyance apparatus coordinate system Σb, a conveyance speed, and the like.

The conveyance apparatus coordinate system Σb is a coordinate system to be a basis at the time of simulatingly causing the conveyor model 233 to operate in the virtual space, and is defined in the virtual space by the origin and axis directions of the conveyance apparatus coordinate system Σb included among the virtual conveyance operation parameters.

As shown in FIG. 10, the origin of the conveyance apparatus coordinate system Σb is arranged at a corner of the upstream end of the conveyor model 233, and the conveyor model 233 conveys the workpiece model 220 in the Y-axis direction of the conveyance apparatus coordinate system Σb.

As shown in FIG. 10, the detection apparatus coordinate system Σc is set such that the Z-axis direction corresponds to the line-of-sight direction of the detection apparatus model 240 and corresponds to the vertically downward direction in the real space.

Thereby, by executing the operation program for the robot and the operation program for the conveyance apparatus, the robot simulation apparatus 1A can control the position of the tool tip point of the grasped object model 210, for example, to press a stamp pad to a workpiece to attach a stamp or the like.

Similarly to the case of the first embodiment, the image generation unit 103 generates an image of the robot system operating on the robot simulation apparatus 1 according to the operation program.

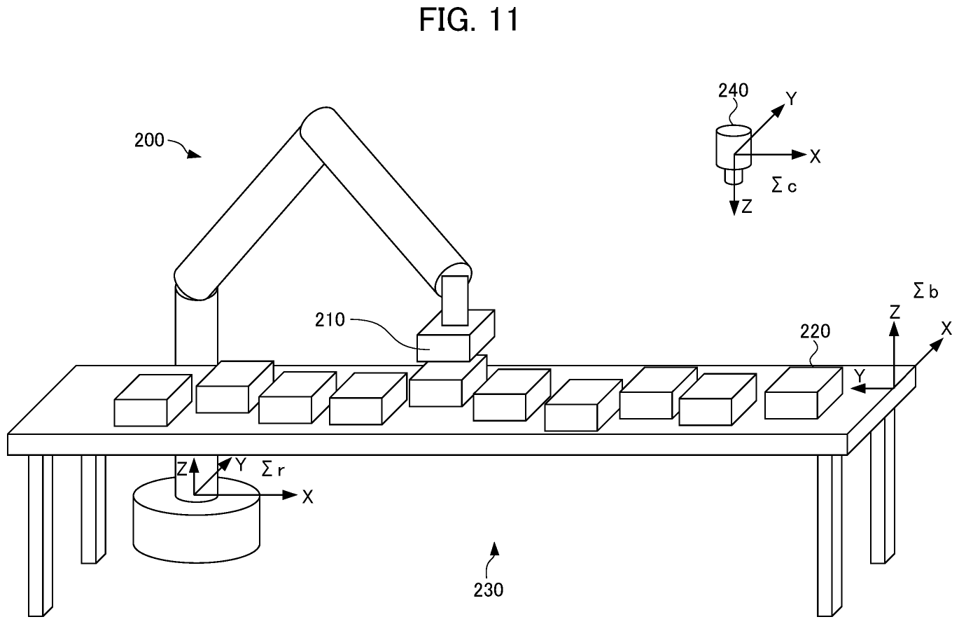

FIG. 11 is a diagram showing an example of an image of the robot system generated by the image generation unit 103.

As shown in FIG. 11, for example, by executing the operation program for the robot and the operation program for the conveyance apparatus, workpiece models 220 are sequentially arranged on the conveyance apparatus model 230 based on a quantity of workpieces supplied per unit time set for the operation programs in advance (for example, one minute). Then, the conveyance apparatus model 230 conveys the sequentially arranged workpiece models 220 in the Y-axis direction of the conveyance apparatus coordinate system Σb at a conveyance speed set for the operation programs in advance.

As shown in FIG. 11, each workpiece model 220 may be given a random amount of offset of a position on an XY plane of the conveyance apparatus coordinate system Σb when being arranged on the surface of the conveyance apparatus model 230.

Similarly to the case of the first embodiment, the first transfer material image display unit 104 displays a transfer material image of a transfer material to be transferred to each workpiece model 220, on the surface of the grasped object model 210.

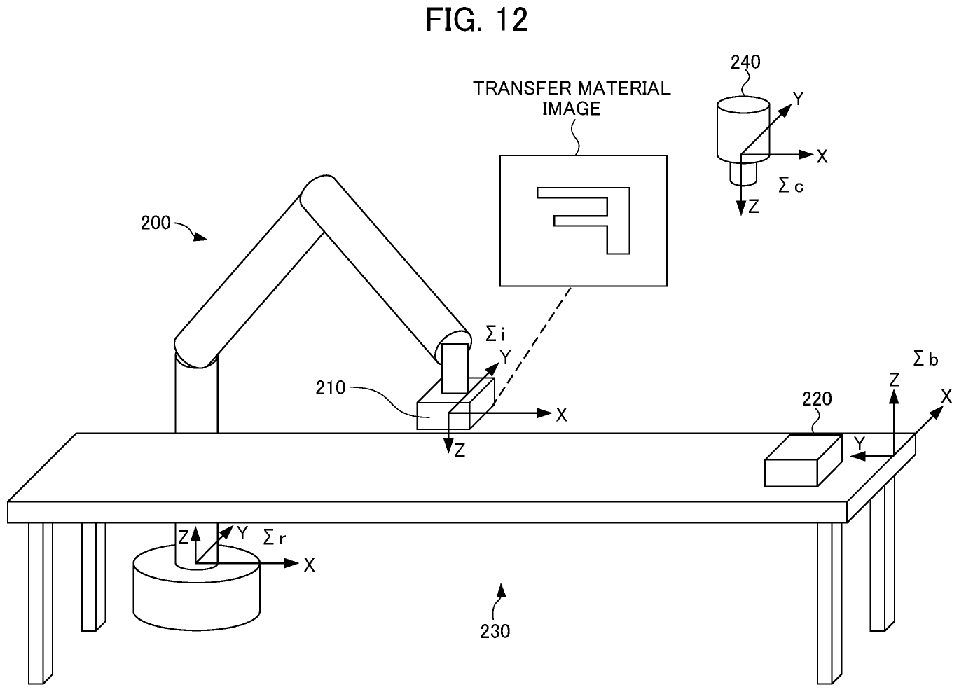

FIG. 12 is a diagram showing an example of a transfer material image of a transfer material displayed being superimposed on the image of the robot system of FIG. 10.

The transfer material image shown in FIG. 12 is an image seen in the minus Z-axis direction of the grasped object coordinate system Σh of the grasped object model 210.

When the surface of the grasped object model 210 comes into contact with the surface of any of the workpiece models 220 conveyed by the conveyance apparatus model 230, the second transfer material image display unit 105a displays the transfer material image on the surface of the workpiece model 220 on the display unit 12 such that the transfer material image is in a relationship of being reversed relative to the transfer material image displayed on the surface of the grasped object model 210.

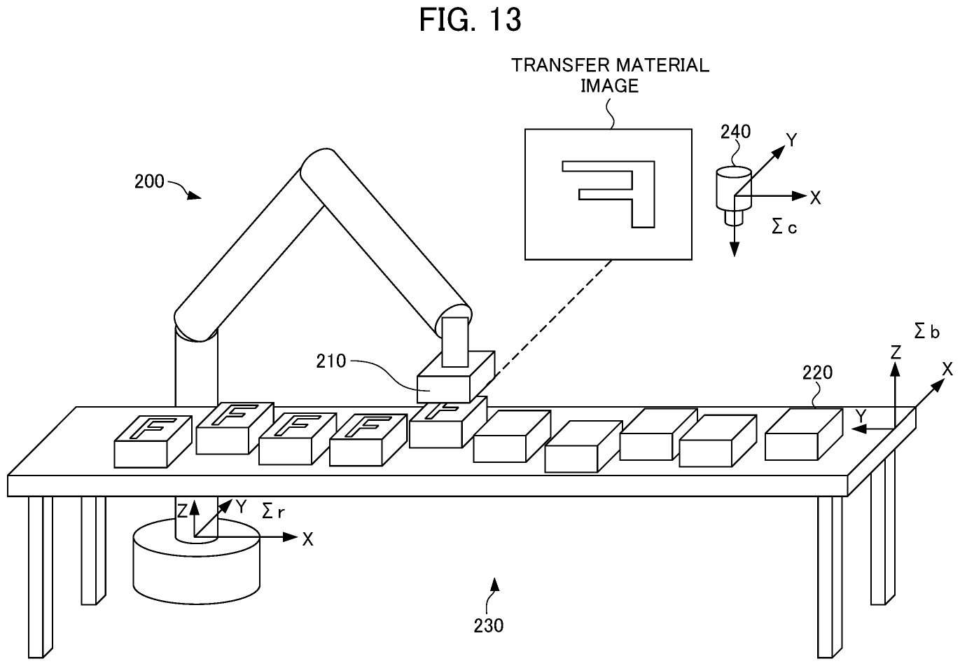

FIG. 13 is a diagram showing an example of the transfer material image transferred onto the surface of the workpiece models 220.

The second transfer material image display unit 105a may superimposingly display the whole transfer material image reversedly transferred to the workpiece models 220, on the display unit 12, as well as displaying the image of FIG. 13 on the display unit 12.

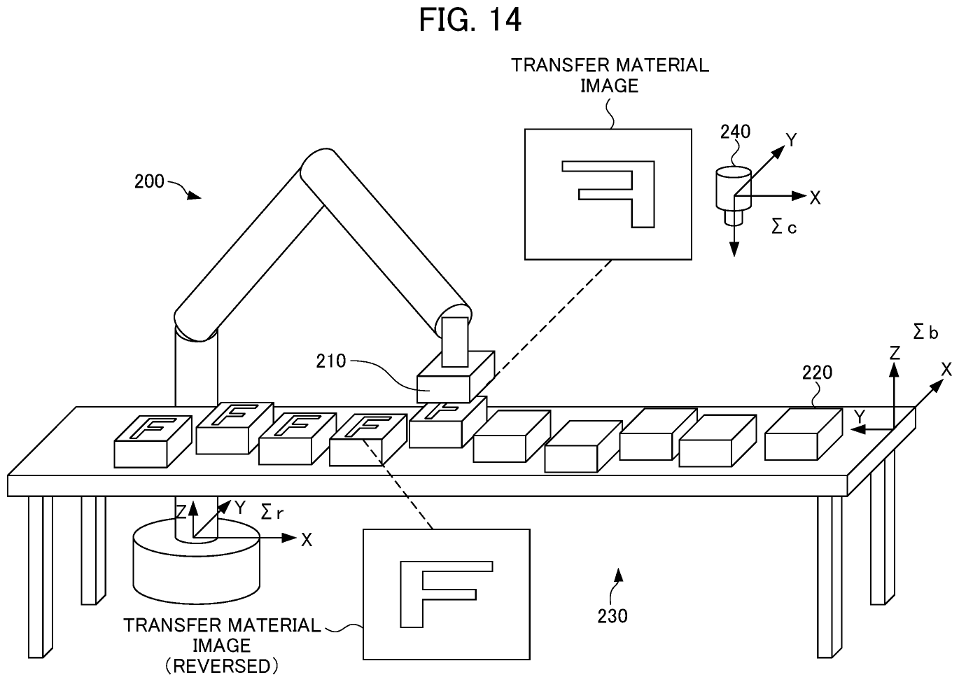

FIG. 14 is a diagram showing an example of the whole transfer material image that has been reversedly transferred, which is superimposedly displayed on the image of FIG. 13.

That is, for example, the robot simulation apparatus 1A causes the detection apparatus model 240 to operate in the virtual space, and the detection apparatus model 240 detects each workpiece model 220 being conveyed. The robot simulation apparatus 1A generates, based on line-of-sight data of the detection apparatus model 240 and arrangement information about each workpiece model 220, a virtually detected image (a virtual detection result) that should be obtained when the detection apparatus model 240 detects the workpiece model 220 in the virtual space.

The robot simulation apparatus 1A acquires the position and posture of the workpiece model 220 in the robot coordinate system Σr, from the generated virtually detected image. Then, the robot simulation apparatus 1A causes the robot model 200 to make motions in the virtual space based on the acquired position and posture of the workpiece model 220 and the operation program for the robot.

The robot simulation apparatus 1A sequentially sets the grasped object coordinate system Σh so that the origin of the grasped object coordinate system Σh is arranged at a predetermined position of each workpiece model 220 being conveyed (for example, the center of the workpiece model 220).

The robot simulation apparatus 1A causes the robot model 200 to make motions in the virtual space so that the grasped object model 210 is arranged at a position and in a posture, the position and posture being specified by the grasped object coordinate system Σh.

Thereby, the robot model 200 can cause the grasped object model 210 to follow the workpiece models 220 in the virtual space.

Then, if the transfer material is attached to the upper surface of each workpiece model 220 as shown in FIG. 13, the robot simulation apparatus 1A (the second transfer material image display unit 105a) may judge that the operation program for the robot has been appropriately constructed.

On the other hand, in the case of failing in attaching the transfer material to the upper surface of any of the workpiece models 220, the robot simulation apparatus 1A (the second transfer material image display unit 105a) may judge that the operation program for the robot has not been appropriately constructed. In this case, the robot simulation apparatus 1A may display a warning image on the display unit 12.

By doing so, the robot simulation apparatus 1A can simulate motions of the robot in the real space, in a form close to actual work, and easily confirm a pattern, a label or the like has reliably been transferred to a workpiece.

The simulation process of the robot simulation apparatus 1A is similar to the case of FIG. 8, and detailed description thereof will be omitted.

As described above, the robot simulation apparatus 1A according to the second embodiment arranges the robot model 200, the grasped object model 210, the workpiece models 220, the conveyance apparatus model 230, and the detection apparatus model 240 in a virtual space. The robot simulation apparatus 1A generates an image of the robot system operating on the robot simulation apparatus 1A according to the operation program, displays the image on the display unit 12, and displays a transfer material image of a transfer material on the surface of the grasped object model 210 on the displayed image. When the surface of the grasped object model 210 comes into contact with the surface of any of the workpiece models 220 conveyed by the conveyance apparatus model 230, the robot simulation apparatus 1A displays the transfer material image on the surface of the workpiece model 220 on the display unit 12 such that the transfer material image is in a relationship of being reversed relative to the transfer material image displayed on the surface of the grasped object model 210, according to a motion of the robot model 200 and the grasped object model 210.

Thereby, the robot simulation apparatus 1A can easily confirm, together with operation of an operation program, that a desired pattern, label or the like has reliably been transferred to a workpiece.

The second embodiment has been described above.

The first and second embodiments have been described above. The robot simulation apparatuses 1 and 1A, however, are not limited to the above embodiments, but modifications, improvements, and the like are included as far as the object can be achieved.

### Modification Example

Though the robot simulation apparatuses 1 and 1A are assumed to be apparatus different from the robot control apparatuses (not shown) in the first and second embodiment described above but are not limited thereto. For example, the robot simulation apparatuses 1 and 1A may be included in the robot control apparatuses (not shown), respectively.

Each of the functions included in the robot simulation apparatuses 1 and 1A in the first and second embodiments can be realized by hardware, software or a combination thereof. Here, being realized by software means being realized by a computer reading and executing a program.

The program can be supplied to the computer by being stored in any of various types of non-transitory computer-readable media. The non-transitory computer-readable media include various types of tangible storage media. Examples of the non-transitory computer-readable media include a magnetic recording medium (for example, a flexible disk, a magnetic tape, or a hard disk drive), a magneto-optical recording medium (for example, a magneto-optical disk), a CD-ROM (read-only memory), a CD-R, a CD-R/W, and a semiconductor memory (for example, a mask ROM, a PROM (programmable ROM), an EPROM (Erasable PROM), a flash ROM, and a RAM). The program may be supplied to the computer by any of various types of transitory computer-readable media. Examples of the transitory computer-readable media include an electrical signal, an optical signal and an electromagnetic wave. The transitory computer-readable media can supply the program to the computer via a wired communication path such as an electrical wire and an optical fiber, or a wireless communication path.

Steps describing the program recorded in a recording medium include not only processes that are performed in time series in the order thereof but also processes that are not necessarily performed in time series but are executed in parallel or individually.

In other words, a robot simulation apparatus of the present disclosure can take various embodiments having the following configuration.
(1) The robot simulation apparatus 1 of the present disclosure is a robot simulation apparatus for performing simulation of an operation program for a robot that, in a robot system including the robot grasping a grasped object and a workpiece in a workspace, presses a surface of the grasped object to a surface of the workpiece object to transfer a transfer material arranged on the surface of the grasped object onto the surface of the workpiece, the robot simulation apparatus including: a robot model arrangement unit that arranges a robot model 200 of the robot in a virtual space that three-dimensionally represents the workspace; a grasped object model arrangement unit that arranges a grasped object model 210 of the grasped object such that the grasped object model 210 is grasped by the robot model 200, in the virtual space; a workpiece model arrangement unit that arranges a workpiece model 220 of the workpiece at a position that the grasped object model 210 grasped by the robot model 200 reaches, in the virtual space; an image generation unit 103 that generates, in the robot simulation apparatus 1, an image of the robot system operating according to the operation program; a display unit 12 that displays the image of the robot system generated by the image generation unit 103; a first transfer material image display unit 104 that displays a transfer material image of the transfer material on a surface of the grasped object model 210; and a second transfer material image display unit 105 that displays, when the surface of the grasped object model 210 comes into contact with a surface of the workpiece model 220, the transfer material image on the surface of the workpiece model 220 such that the transfer material image is in a relationship of being reversed relative to the transfer material image displayed on the surface of the grasped object model 210.

According to the robot simulation apparatus 1, it is possible to easily confirm, together with operation of an operation program, that a desired pattern, a label or the like has reliably been transferred to a workpiece.
(2) In the robot simulation apparatus 1A according to (1), the robot system further includes a conveyance apparatus that conveys the workpiece and a detection apparatus that detects the workpiece being conveyed by the conveyance apparatus; the robot simulation apparatus 1A further includes: a conveyance model arrangement unit that arranges a conveyance apparatus model 230 of the conveyance apparatus in the virtual space; a workpiece model arrangement unit that arranges the workpiece model 220 of the workpiece on the conveyance apparatus model 230 in the virtual space; and a detection apparatus model arrangement unit that arranges a detection apparatus model 240 of the detection apparatus that detects the workpiece model 220 conveyed by the conveyance apparatus model 230, in the virtual space, such that the detection apparatus model 240 is able to detect the workpiece model 220 conveyed by the conveyance apparatus model 230, in the virtual space; and the second transfer material image display unit 105a may further display, when the surface of the grasped object model 210 comes into contact with the surface of the workpiece model 220 conveyed by the conveyance apparatus model 230, the transfer material image on the surface of the workpiece model 220 such that the transfer material image is in a relationship of being reversed relative to the transfer material image displayed on the surface of the grasped object model 210.

By doing so, the robot simulation apparatus 1A can have effects similar to those of (1).

### EXPLANATION OF REFERENCE NUMERALS

1, 1A: Robot simulation apparatus
10: Control unit
101: Virtual space creation unit
102, 102a: Model arrangement unit
103: Image generation unit
104: First transfer material image display unit
105, 105a: Second transfer material image display unit
11: Input unit
12: Display unit
13: Storage unit
131: Model data

1. A robot simulation apparatus for performing simulation of an operation program for a robot that, in a robot system comprising the robot grasping a grasped object and a workpiece in a workspace, presses a surface of the grasped object to a surface of the workpiece to transfer a transfer material arranged on the surface of the grasped object onto the surface of the workpiece, the robot simulation apparatus comprising:
a robot model arrangement unit configured to arrange a robot model of the robot in a virtual space that three-dimensionally represents the workspace;
a grasped object model arrangement unit configured to arrange a grasped object model of the grasped object such that the grasped object model is grasped by the robot model, in the virtual space;
a workpiece model arrangement unit configured to arrange a workpiece model of the workpiece at a position that the grasped object model grasped by the robot model reaches, in the virtual space;
an image generation unit configured to generate, in the robot simulation apparatus, an image of the robot system operating according to the operation program;
a display unit configured to display the image of the robot system generated by the image generation unit;
a first transfer material image display unit configured to display a transfer material image of the transfer material on a surface of the grasped object model; and
a second transfer material image display unit configured to display, when the surface of the grasped object model comes into contact with a surface of the workpiece model, the transfer material image on the surface of the workpiece model such that the transfer material image is in a relationship of being reversed relative to the transfer material image displayed on the surface of the grasped object model.

2. The robot simulation apparatus according to claim 1, wherein
the robot system further comprises a conveyance apparatus configured to convey the workpiece and a detection apparatus configured to detect the workpiece being conveyed by the conveyance apparatus;
the robot simulation apparatus further comprises:
a conveyance model arrangement unit configured to arrange a conveyance apparatus model of the conveyance apparatus in the virtual space;
a workpiece model arrangement unit configured to arrange the workpiece model of the workpiece on the conveyance apparatus model in the virtual space; and
a detection apparatus model arrangement unit configured to arrange a detection apparatus model of the detection apparatus that detects the workpiece model conveyed by the conveyance apparatus model, in the virtual space, such that the detection apparatus model is able to detect the workpiece model conveyed by the conveyance apparatus model, in the virtual space; and
the second transfer material image display unit further
displays, when the surface of the grasped object model comes into contact with the surface of the workpiece model conveyed by the conveyance apparatus model, the transfer material image on the surface of the workpiece model such that the transfer material image is in the relationship of being reversed relative to the transfer material image displayed on the surface of the grasped object model.
